(19) United States
(12) Patent Application Publication
(10) Pub. No.: US 2013/0342261 A1
(43) Pub. Date: Dec. 26, 2013

(54) BIAS AND LOAD CIRCUIT, FAST BIAS CIRCUIT AND METHOD

(71) Applicant: NOVATEK MICROELECTRONICS CORP., Hsinchu (TW)

(72) Inventor: Ying-Chung Chiu, Hsinchu County (TW)

(73) Assignee: NOVATEK MICROELECTRONICS CORP., Hsinchu (TW)

(21) Appl. No.: 13/649,117

(22) Filed: Oct. 11, 2012

(30) Foreign Application Priority Data
Jun. 25, 2012 (TW) 101122646

(51) Int. Cl. H03K 17/04

(52) U.S. Cl. 327/374

(57) ABSTRACT

A fast bias circuit including a bias unit, a resistor, a first switch, and a detecting circuit is provided. The resistor has a first terminal coupled to the bias unit to receive a bias voltage, and a second terminal coupled to a bias terminal of a target circuit, wherein the bias terminal is coupled to an input signal. The first switch has a first terminal coupled to the first terminal of the resistor, a second terminal coupled to the second terminal of the resistor, and a control terminal coupled to the detecting circuit. During an initialisation period, the detecting circuit compares the bias voltage with a voltage at the bias terminal of the target circuit to obtain a comparison result, and controls the first switch according to the comparison result. Furthermore, a fast bias method and a bias and load circuit are also provided.

### CROSS-REFERENCE TO RELATED APPLICATION

This application claims the priority benefit of Taiwan application serial no. 101122646, filed on Jun. 25, 2012. The entirety of the above-mentioned patent application is hereby incorporated by reference herein and made a part of this specification.

### BACKGROUND

1. Technical Field

The disclosure relates to a bias circuit. Particularly, the disclosure relates to a bias and load circuit, and a fast bias circuit and a method thereof.

2. Related Art

Generally, bias methods are grouped into two types, and one type is a direct current (DC) coupling, and another type is an alternating current (AC) coupling. Compared to the AC coupling, the DC coupling has an advantage of faster bias response time, though it has a problem that a DC offset thereof cannot be eliminated, and the DC offset is even output to a next stage circuit, by which the DC offset is amplified. If the AC coupling is applied, DC levels of an anterior circuit and a posterior circuit are not mutually influenced, so that the problem of DC offset is avoided. However, the AC coupling circuit has a problem of longer bias response time. Regardless of the AC coupling or the DC coupling, it is an important issue to shorten the bias response time.

### SUMMARY

The disclosure is directed to a fast bias circuit, which is capable of fast providing a bias voltage to a bias terminal of a target circuit in an initialisation period, so as to shorten a bias time.

The disclosure is directed to a fast bias method, which is capable of shortening a transient response time of a voltage at a bias terminal according to a comparison result of the voltage at the bias terminal of a target circuit and a bias voltage.

The disclosure provides a fast bias circuit including a bias unit, a resistor, a first switch, and a detecting circuit. The resistor has a first terminal and a second terminal, where the first terminal is coupled to the bias unit to receive a bias voltage, and the second terminal is coupled to a bias terminal of a target circuit. The bias terminal is coupled to an input signal of the fast bias circuit. The first switch has a first terminal coupled to the first terminal of the resistor, a second terminal coupled to the second terminal of the resistor, and a control terminal. The detecting circuit is coupled to the control terminal of the first switch. During an initialisation period, the detecting circuit compares the bias voltage with a voltage at the bias terminal of the target circuit to obtain a comparison result, and controls a conduction state of the first switch according to the comparison result.

In an embodiment of the disclosure, the bias unit provides the bias voltage during a power-on period of the target circuit, and does not provide the bias voltage during a power off period of the target circuit.

In an embodiment of the disclosure, the bias unit further includes a bias voltage source and a second switch. The bias voltage source provides the bias voltage. A first terminal of the second switch is coupled to the bias voltage source for receiving the bias voltage, and a second terminal of the second switch is coupled to the first terminal of the resistor.

In an embodiment of the disclosure, the second switch is turned off during the power off period, and the second switch is turned on during the power-on period.

In an embodiment of the disclosure, during the initialisation period, the detecting circuit compares the bias voltage with the voltage at the bias terminal of the target circuit. When the voltage at the bias terminal of the target circuit does not reach the bias voltage during the initialisation period, the detecting circuit controls the first switch to be in a turn-on state. When the voltage at the bias terminal of the target circuit reaches the bias voltage, the initialisation period is ended. After the initialisation period is ended, the detecting circuit controls the first switch to maintain in a turn-off state.

In an embodiment of the disclosure, the detecting circuit further includes a comparator and a logic unit. A first input terminal and a second input terminal of the comparator are respectively coupled to the bias unit and the bias terminal of the target circuit, and an output terminal of the comparator is coupled to the control terminal of the first switch. The logic unit is coupled to an enabling terminal of the comparator, where during the initialisation period of the power-on period of the target circuit, the logic unit enables the comparator. When an output of the comparator indicates that the voltage at the bias terminal of the target circuit reaches the bias voltage, the initialisation period is ended. After the initialisation period is ended, the logic unit keeps disabling the comparator.

In an embodiment of the disclosure, the fast bias circuit further includes a third switch. A first terminal of the third switch is coupled to the bias terminal of the target circuit. A second terminal of the third switch is coupled to a reference voltage.

The disclosure further provides a bias and load circuit including the aforementioned fast bias circuit and the target circuit. The target circuit is driven by the fast bias circuit during a power-on period, and is not driven by the fast bias circuit during a power off period.

In an embodiment of the disclosure, the target circuit includes a load and a switch device, where the switch device is coupled between the load and a reference voltage, and is turned on or turned off according to a voltage at the bias terminal.

In an embodiment of the disclosure, the switch device includes a switch transistor, where the switch transistor has a first source/drain coupled to the load, a second source/drain coupled to the reference voltage, and a gate serving as the bias terminal.

The disclosure provides a fast bias method including following steps. A bias voltage is provided to a first terminal of a resistor during a power-on period of a target circuit, where a second terminal of the resistor is coupled to a bias terminal of the target circuit, and the bias terminal is coupled to an input signal of a fast bias circuit. During an initialisation period of the power-on period, the bias voltage is compared with a voltage at the bias terminal of the target circuit to obtain a comparison result. It is determined whether or not to short the second terminal of the resistor to the first terminal of the resistor according to the comparison result.

In an embodiment of the disclosure, the fast bias method further includes: not to provide the bias voltage to the first terminal of the resistor during a power off period of the target circuit.

In an embodiment of the disclosure, the step of determining whether or not to short the second terminal of the resistor to the first terminal of the resistor includes shorting the first terminal and the second terminal of the resistor when the voltage at the bias terminal of the target circuit does not reach the bias voltage during the initialisation period; ending the initialisation period when the voltage at the bias terminal of the target circuit reaches the bias voltage; and not to short the first terminal and the second terminal of the resistor after the initialisation period is ended.

In an embodiment of the disclosure, the fast bias method further includes coupling the bias terminal of the target circuit to a reference voltage during a power off period of the target circuit, and removing the reference voltage from the bias terminal of the target circuit during the power-on period.

According to the above descriptions, in the embodiment of the disclosure, during the initialisation period of the power-on period, the fast bias circuit compares the bias voltage with the voltage at the bias terminal of the target circuit, and obtains the comparison result to control a conduction state of the first switch, so as to achieve a fast bias effect.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of an alternating current (AC) coupling bias circuit.

FIG. 2 is a schematic diagram of a fast bias circuit according to an embodiment of the disclosure.

FIG. 3 is a circuit block diagram of a detecting circuit of FIG. 2 according to an embodiment of the disclosure.

FIG. 4 is relationship diagram of bias response time of bias terminals of target circuits of the embodiments of FIG. 1 and FIG. 2.

FIG. 5A is a circuit schematic diagram of a fast bias circuit of FIG. 2 in a power off period.

FIG. 5B is a circuit schematic diagram of a fast bias circuit of FIG. 2 in an initialisation period of a power-on period.

FIG. 5C is a circuit schematic diagram of a fast bias circuit of FIG. 2 in a power-on period after an initialisation period is ended.

FIG. 6 is a flowchart illustrating a fast bias method according to an embodiment of the intention.

FIG. 7 is a schematic diagram of a fast bias circuit according to another embodiment of the disclosure.

### DETAILED DESCRIPTION OF DISCLOSED EMBODIMENTS

In the disclosure, usage of a term “one embodiment” or the similar expression refers to that a specific feature, structure or characteristic described with reference of the concrete embodiment are included in at least one specific embodiment of the disclosure. Therefore, in the disclosure, the term “in a specific embodiment” and the similar expression unnecessarily refer to a same specific embodiment.

In the disclosure (including the claims), a term “couple” refers to directly or indirectly connect. For example, if it is described that a first device is coupled to a second device, it can be implemented that the first device is directly connected to the second device, and it can also be implemented that the first device is indirectly connected to the second device through other devices or a certain connection means.

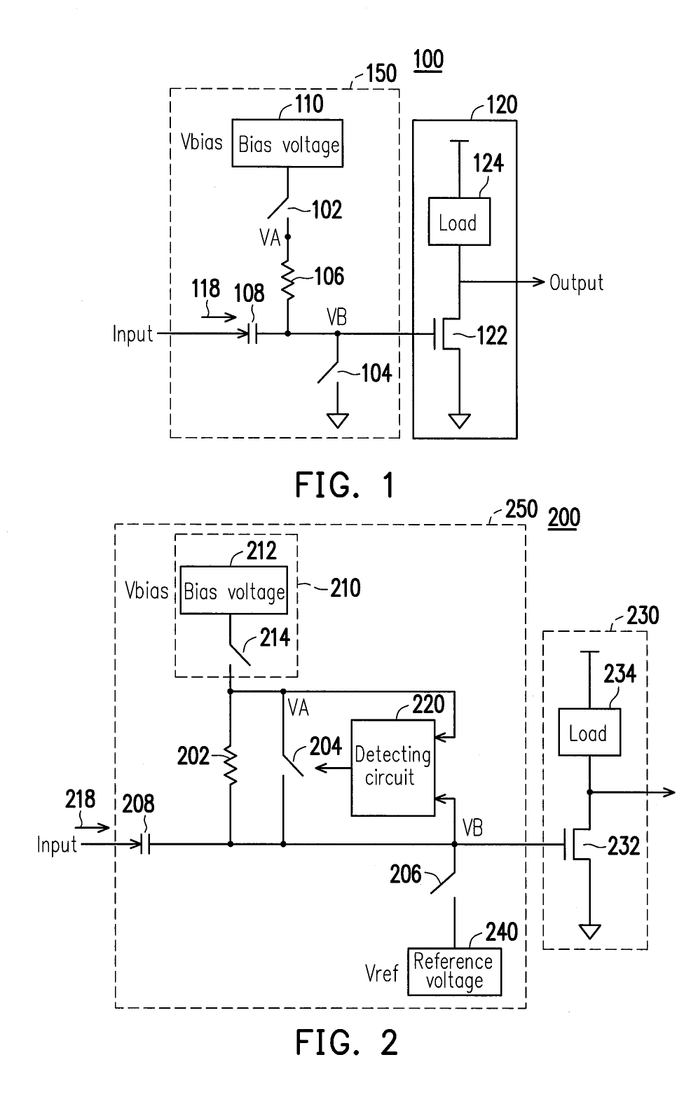

FIG. 1 is a schematic diagram of an alternating current (AC) coupling bias circuit. Referring to FIG. 1, a bias and load circuit 100 includes a target circuit 120 and a bias circuit 150. The target circuit 120 includes a switch transistor 122 and a load 124, wherein a gate of the switch transistor 122 can serve as a bias terminal VB of the target circuit 120. In the target circuit 120, the load 124 is coupled to a first source/drain (for example, a drain) of the switch transistor 122, and a second source/drain (for example a source) of the switch transistor 122 is coupled to a reference voltage (for example, a ground voltage).

In the bias circuit 150, an input signal 118 is input to the bias terminal VB of the target circuit 120 through a capacitor 108. A bias voltage source 110 provides a bias voltage Vbias to a node VA through a switch 102, and the bias terminal VB of the target circuit 120 is coupled to the ground voltage through a switch 104. During a power off period of the target circuit 120, the switch 102 can be set in a turn-off state, and the switch 104 can be set in a turn-on state. Since the switch 104 is in the turn-on state, the gate of the switch transistor 122 of the target circuit 120 is coupled to the ground voltage, so that during the power off period of the target circuit 120, the switch transistor 122 is maintained in the turn-off state.

During a power-on period of the target circuit 120, the switch 102 is set in the turn-on state, and the switch 104 is set in the turn-off state. Since the switch 102 is in the turn-on state, the bias voltage source 110 can provide the bias voltage Vbias to the node VA. In an initialisation period (a transient period) of the power-on period, a voltage of the node VA is about the bias voltage Vbias, and a voltage at the bias terminal VB is about the ground voltage. The bias voltage Vbias at the node VA charges the bias terminal VB of the target circuit 120 through a resistor 106, so that the voltage at the bias terminal VB is pulled up from the ground voltage to the bias voltage Vbias in a certain speed during the initialisation period. However, a time (a bias response time) required for pulling up the voltage at the bias terminal VB to the bias voltage Vbias is determined by a resistance of the resistor 106. For example, if the resistance of the resistor 106 is excessively large, the bias response time of the booted target circuit 120 after activation can be excessively long.

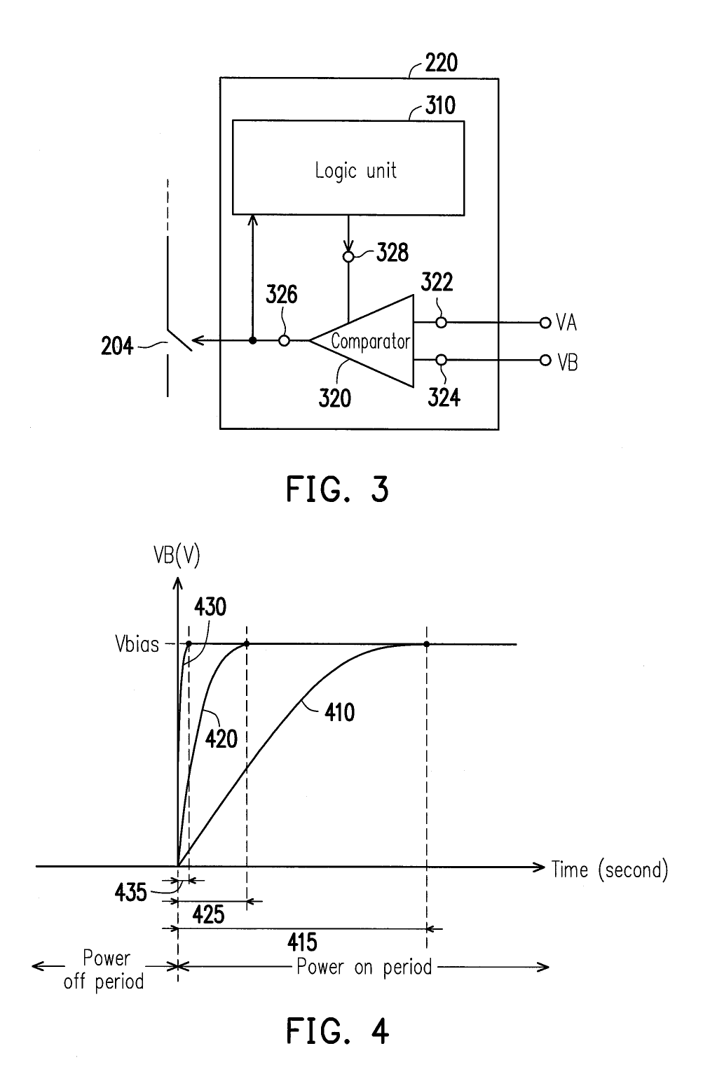

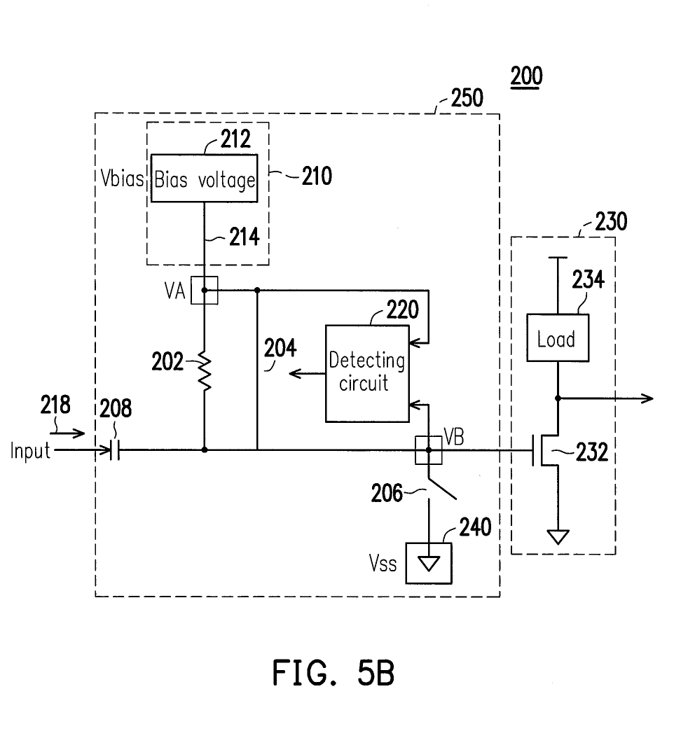

Referring to FIG. 4, FIG. 4 is relationship diagram of bias response time of the embodiment of FIG. 1 and embodiment of FIG. 2. A vertical axis in FIG. 4 represents the voltage at the bias terminal VB of the target circuit, and a horizontal axis represents time. A voltage variation of the bias terminal VB of the target circuit 120 of FIG. 1 is shown as a first bias curve 410 for a configuration where the resistance of the resistor 106 is 2 MΩ, for example. In an initial stage of the power-on period, the voltage at the bias terminal VB can reach the bias voltage Vbias only after a bias response time 415. On the other hand, for another configuration where the resistance of the resistor 106 is 1 MΩ, the voltage variation of the bias terminal VB of the target circuit 120 of FIG. 1 is shown as a second bias curve 420. In this case, the voltage at the bias terminal VB can reach the bias voltage Vbias after a bias response time 425. Comparing the bias curves 410 and 420 and the respective lengths of bias response time, the greater the resistance of the resistor 106 is, the longer the bias response time is. Therefore, according to FIG. 4, it can be observed that the magnitude of the resistance of the resistor 106 influences the bias response time. However, the smaller the resistance of the resistor 106 is, the easier the bias voltage Vbias of the power voltage source 110 interferes transmission of the input signal 118.

FIG. 2 is a schematic diagram of a fast bias circuit and a bias and load circuit applying the fast bias circuit according to an embodiment of the disclosure. Related descriptions of FIG. 1 can be referred to those for the embodiment of FIG. 2. In the present embodiment, the bias and load circuit 200 includes a target circuit 230 and a fast bias circuit 250 coupled to the target circuit 230. In the power-on period, the target circuit 230 is driven by the fast bias circuit 250, and in the power off period, the target circuit 230 is not driven by the fast bias circuit 250.

The target circuit 230 includes a switch device and a load 234. The switch device is coupled between the load 234 and a reference voltage. The switch device is turned on or turned off according to the voltage at the bias terminal VB. The switch device can be any switch circuit. For example, the switch device of the embodiment of FIG. 2 includes a switch transistor 232, where a gate of the switch transistor 232 can serve as the bias terminal VB of the target circuit 230. Similar to the target circuit 120 of FIG. 1, in the target circuit 230, the load 234 is coupled to a first source/drain (for example, a drain) of the switch transistor 232, and a second source/drain (for example a source) of the switch transistor 232 is coupled to the reference voltage (for example, the ground voltage). It should be noticed that the switch transistor 232 is not limited to be an N-channel transistor, and in other embodiments, the switch transistor 232 can be a P-channel transistor, or can be replaced by other switch devices. Moreover, in the embodiment of FIG. 2, although the switch transistor 232 and the load 234 are used to implement the target circuit 230, an actual implementation of the target circuit 230 is not limited thereto. For example, in other embodiments, the target circuit 230 can be an amplifier, a modulator or other analog signal processing circuits.

Referring to FIG. 2, the fast bias circuit 250 includes a bias unit 210, a resistor 202, a first switch 204, a capacitor 208, a detecting circuit 220 and a third switch 206. The resistor 202, the first switch 204 and the detecting circuit 220 are coupled in parallel between the node VA and the bias terminal VB of the target circuit 230. The bias unit 210 is coupled to the node VA. One terminal of the capacitor 208 is coupled to the bias terminal VB of the target circuit 230, and another terminal thereof receives an input signal 218 of the fast bias circuit 250. One terminal of the third switch 206 is coupled to a reference voltage source 240 for receiving a reference voltage Vref, and another terminal thereof is coupled to the bias terminal VB of the target circuit 230.

During the power-on period of the target circuit 230, the bias unit 210 provides the bias voltage Vbias to the node VA. During the power off period of the target circuit 230, the bias unit 210 does not provide the bias voltage Vbias to the node VA. FIG. 2 also illustrates an exemplary circuit structure of the bias unit 210. In the present embodiment, the bias unit 210 includes a bias voltage source 212 and a second switch 214, where one terminal of the second switch 214 is coupled to the bias voltage source 212, and another terminal thereof is coupled to the node VA. During the power-on period of the target circuit 230, the second switch 214 is set to the turn-on state, and during the power off period of the target circuit 230, the second switch 214 is set to the turn-off state.

It should be noticed that implementation of the bias unit 210 is not limited to that in the embodiment of FIG. 2. The bias unit 210 can be controlled by other controllers to determine whether or not to provide the bias voltage Vbias. In other embodiments, the bias unit 210 can also be implemented by the other bias voltage source having an enabling terminal or a switch control function. Moreover, in the other embodiments, the switch 214 of the bias unit 210 can be omitted, and the bias voltage source 212 directly provides the bias voltage Vbias to the node VA.

During the power off period of the target circuit 230, the first switch 204 and the second switch 214 can be set in the turn-off state, and the third switch 206 can be set in the turn-on state. Since the third switch 206 is in the turn-on state, the reference voltage Vref can be provided to the bias terminal VB of the target circuit 230. In the embodiment of FIG. 2, the reference voltage provided by the reference voltage source 240 can be the ground voltage. During the power off period of the target circuit 230, since the gate of the switch transistor 232 is coupled to the ground voltage through the third switch 206 in the turn-on state, it is ensured that the switch transistor 232 is maintained in the turn-off state during the power off period. In other embodiments, a level of the reference voltage is not limited to the ground voltage, which can be designed to other levels capable of maintaining the switch transistor 232 in the turn-off state during the power off period. Moreover, according to a design requirement of an actual product, the reference voltage provided by the reference voltage source 240 can be a system voltage, the ground voltage or other fixed voltages.

In other embodiments, one of or both of the third switch 206 and the reference voltage source 240 can be omitted. For example, the third switch 206 and the reference voltage source 240 may be omitted if the switch transistor 232 can be maintained to the turn-off state when the bias terminal VB is in a floating state, or a pull down circuit may be used to pull down the voltage at the bias terminal VB during the power off period, or the target circuit 230 itself may ignore a voltage state of the bias terminal VB during the power off period.

During the power-on period of the target circuit 230, the second switch 214 can be set in the turn-on state, and the third switch 206 can be set in the turn-off state. Since the second switch 214 is in the turn-on state, the bias voltage Vbias can be provided to the node VA. During the initialisation period (the transient period) of the power-on period, the voltage of the node VA is about the bias voltage Vbias, and the voltage at the bias terminal VB is about the reference voltage Vref (for example, the ground voltage). Moreover, during the initialisation period of the power-on period, the detecting circuit 220 compares the bias voltage Vbias of the node VA with the voltage at the bias terminal VB of the target circuit 230 to obtain a comparison result, and controls a conduction state of the first switch 204 according to the comparison result. In detail, in the initialisation period, if the bias voltage Vbias of the node VA is different to the voltage at the bias terminal VB of the target circuit 230, the detecting circuit 220 controls the first switch 204 to be in the turn-on state. If the bias voltage Vbias of the node VA is substantially the same as the voltage at the bias terminal VB of the target circuit 230, the initialisation period is ended. After the initialisation period is ended, the detecting circuit 220 controls the first switch 204 to be maintained in the turn-off state.

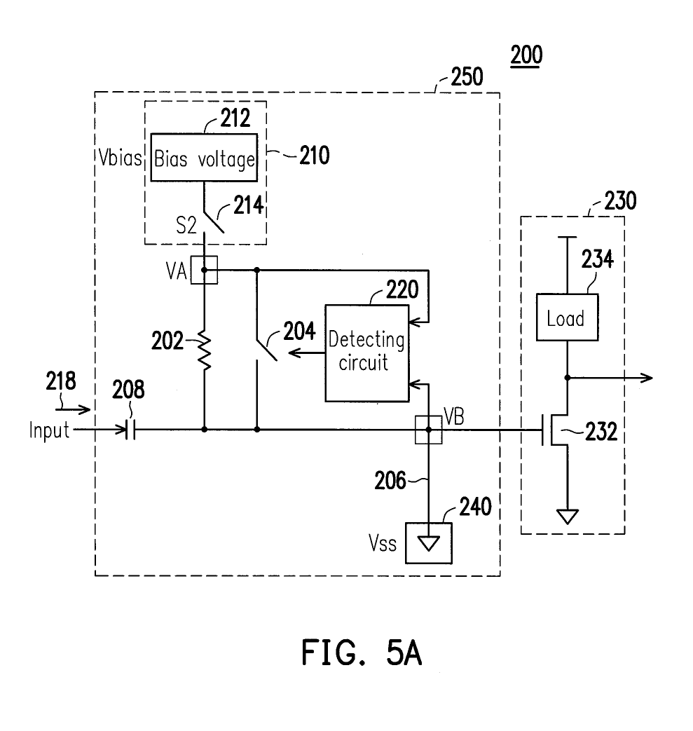

FIG. 3 is a circuit block diagram of the detecting circuit 220 of FIG. 2 according to an embodiment of the disclosure. The detecting circuit 220 includes a logic unit 310 and a comparator 320. The comparator 320 has a first input terminal 322, a second input terminal 324, an output terminal 326 and an enabling terminal 328, where the two input terminals 322 and 324 of the comparator 320 are respectively coupled to the node VA and the bias terminal VB of the target circuit. The output terminal 326 of the comparator 320 is coupled to the control terminal of the first switch 204. The logic unit 310 is coupled to the enabling terminal 328 of the comparator 320.

In the present embodiment, during the power off period of the target circuit 230, the detecting circuit 220 can be set to a disabled state, so that the first switch 204 is maintained to the turn-off state. During the initialisation period of the power-on period of the target circuit 230, the logic unit 310 may enable the comparator 320. During the initialisation period, if a signal at the output terminal 326 of the comparator 320 indicates that the bias voltage Vbias of the node VA is different to the voltage at the bias terminal VB of the target circuit (i.e. the voltage at the bias terminal VB does not reach the bias voltage Vbias), the first switch 204 can be controlled by the comparator 320 to be in the turn-on state. According to the signal at the output terminal 326 of the comparator 320, the logic unit 310 can continue to enable the comparator 320.

When the signal at the output terminal 326 of the comparator 320 indicates that the bias voltage Vbias of the node VA is substantially the same as the voltage at the bias terminal VB of the target circuit (i.e. the voltage at the bias terminal VB reaches the bias voltage Vbias), the first switch 204 controlled by the comparator 320 is transited to the turn-off state. Moreover, when the signal at the output terminal 326 indicates that the voltage at the bias terminal VB reaches the bias voltage Vbias of the node VA, the logic unit 310 determines that the initialisation period is ended. After the initialisation period is ended, the logic unit 310 keeps disabling the comparator 320. Since the comparator 320 is disabled, the first switch 204 controlled by the comparator 320 is maintained to the turn-off state.

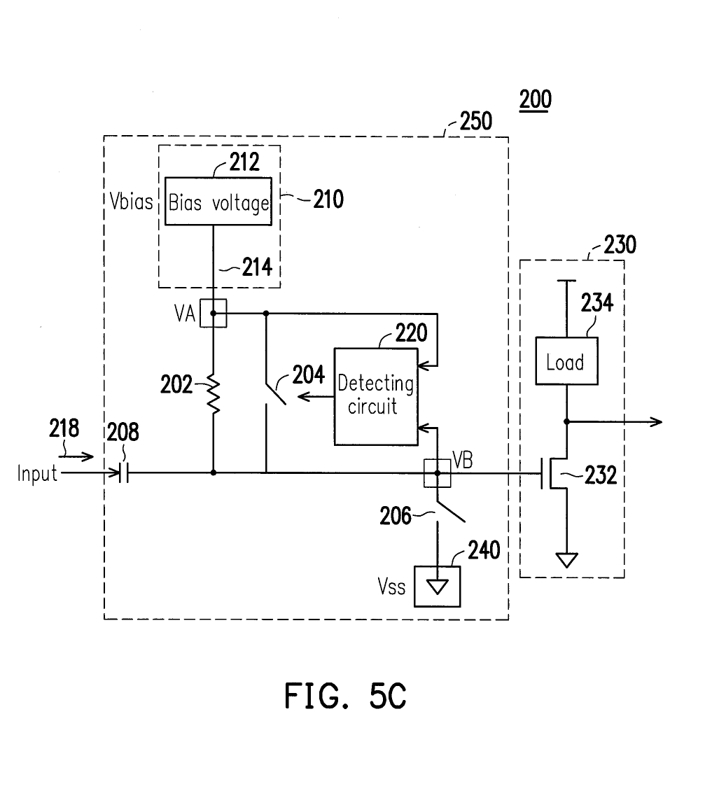

FIG. 5A is a circuit schematic diagram of the fast bias circuit 250 of FIG. 2 in the power off period. In the present embodiment, the target circuit 230 includes an N-channel metal oxide semiconductor (NMOS) transistor 232 and a load 234. Referring to FIG. 5A, during the power off period, the first switch 204 and the second switch 214 are both in the turn-off state, the detecting circuit 220 is in the disabled state, and the third switch 206 is in the turn-on state. Therefore, the bias terminal VB of the target circuit 230 is coupled to the reference voltage (for example, a ground voltage Vss).

FIG. 5B is a circuit schematic diagram of the fast bias circuit 250 of FIG. 2 in the initialisation period of the power-on period. During the power-on period, the third switch 206 is transited to the turn-off state, and the second switch 214 is in the turn-on state. Therefore, the voltage of the node VA is the bias voltage Vbias. During the initialisation period of the power-on period, the detecting circuit 220 is in an enabled state. Therefore, the detecting circuit 220 compares the voltages at the node VA and the bias terminal VB. Since the bias voltage Vbias of the node VA is greater than the ground voltage Vss at the bias terminal VB, the first switch 204 is transited to the turn-on state under control of the detecting circuit 220. Since the first switch 204 is in the turn-on state, the node VA is shorted to the bias terminal VB of the target circuit, so that the bias voltage Vbias fast charges the bias terminal VB of the target circuit.

When the detecting circuit 220 obtains the comparison result indicating that the voltages at the node VA and the bias terminal VB of the target circuit are equivalent, the initialisation period is ended, and the first switch 204 is transited to the turn-off state, as that shown in FIG. 5C. FIG. 5C is a circuit schematic diagram of the fast bias circuit 250 of FIG. 2 in the power-on period after the initialisation period is ended. After the initialisation period is ended, the detecting circuit 220 maintains the first switch 204 to the turn-off state, and the detecting circuit 220 is changed to the disabled state. Since the first switch 204 is in the turn-off state, the first switch 204 does not influence transmission of the input signal 218.

Referring to FIG. 2 and FIG. 4, a third bias curve 430 represents a voltage variation of the bias terminal VB of the target circuit 230 of FIG. 2. During the power off period of the target circuit 230, the voltage at the bias terminal VB is pulled down to the reference voltage Vref by the reference voltage source 240. During the initialisation period of the power-on period of the target circuit 230 (i.e. a bias response time 435 of FIG. 4), since the first switch 204 is in the turn-on state, the voltage at the bias terminal VB can quickly reach the bias voltage Vbias, so as to quickly end the initialisation period. After the initialisation period (i.e. the bias response time 435 of FIG. 4) is ended, the first switch 204 is maintained to the turn-off state, so that the first switch 204 does not influence transmission of the input signal 218. On the other hand, due to the contribution of the first switch 204, an impedance of the resistor 202 can be set to a high resistance value (for example, 2 MΩ or more) without causing excessively long initialisation period (the bias response time).

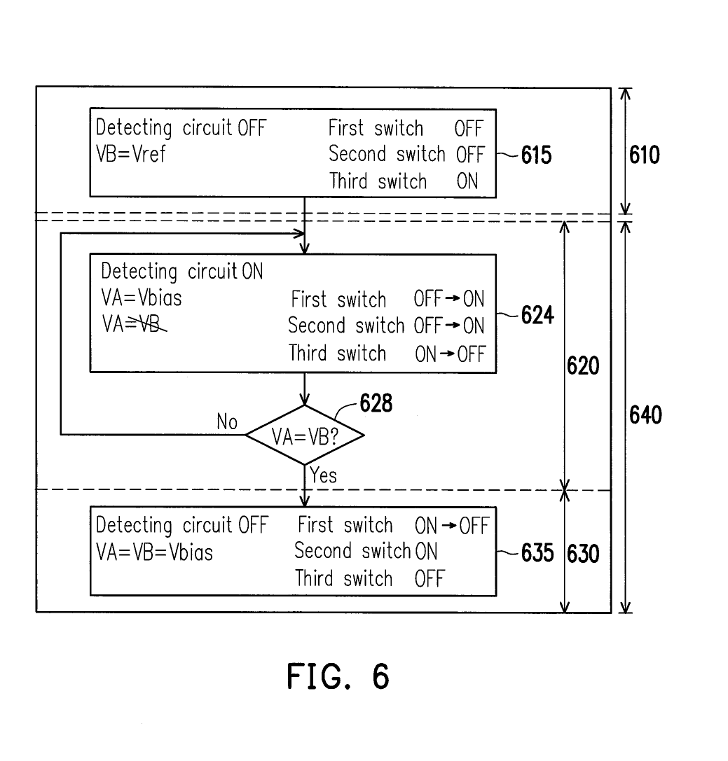

FIG. 6 is a flowchart illustrating a fast bias method according to an embodiment of the intention. The flowchart of the method shown in FIG. 6 is described with reference of the circuit schematic diagram of FIG. 2. In other words, the circuit of FIG can use but is not limited to use the fast bias method of FIG. 6, and the fast bias method of FIG. 6 can be but is not limited to be implemented by the circuit of FIG. 2. Referring to FIG. 6 and FIG. 2, in a power off period 610, the first switch 204 and the second switch 214 are both in the turn-off state, the detecting circuit 220 is in the disabled state, and the third switch 206 is in the turn-on state. Therefore, the bias voltage Vbias is not provided to the first terminal of the resistor 202, and the voltage at the bias terminal VB is the reference voltage Vref (step 615).

Referring to FIG. 6 and FIG. 2, in a power-on period 640, the third switch 206 is transited to the turn-off state, and the second switch 214 is transited to the turn-on state. Therefore, the bias voltage Vbias is provided to the first terminal of the resistor 202 (the node VA). During an initialisation period 620 of the power-on period 640, the detecting circuit 220 is in the enabled state. Therefore, the detecting circuit 220 can compare the bias voltage Vbias of the node VA with the voltage at the bias terminal VB to obtain a comparison result. According to the comparison result, the detecting circuit 220 determines whether or not to control the first switch 204 to short the second terminal of the resistor 202 to the first terminal of the resistor 202. Since the bias voltage Vbias of the node VA is not equal to the reference voltage Vref of the bias terminal VB, the first switch 204 is transited to the turn-on state under control of the detecting circuit 220. Since the first switch 204 is in the turn-on state, the node VA is shorted to the bias terminal VB of the target circuit (step 624).

Referring to FIG. 6 and FIG. 2, when the detecting circuit 220 obtains the comparison result, in step 628, it is determined whether the voltage at the bias terminal VB is equal to the bias voltage Vbias of the node VA. If it is determined that the bias voltage Vbias of the node VA is not equal to the voltage at the bias terminal VB of the target circuit in the step 628, the initialisation period 620 of the power-on period 640 is still maintained, and is the process returns to the step 624. If it is determined that the bias voltage Vbias of the node VA is equal to the voltage at the bias terminal VB of the target circuit in the step 628, the detecting circuit 220 transits the first switch 204 to the turn-off state, and ends the initialisation period 620 of the power-on period 640 to enter a normal operation period 630.

Referring to FIG. 6 and FIG. 2, during the normal operation period 630, the detecting circuit 220 maintains the first switch 204 to the turn-off state, and the detecting circuit 220 is changed to the disabled state. The second switch 214 is maintained to the turn-on state, and the third switch 206 is maintained in the turn-off state (step 635).

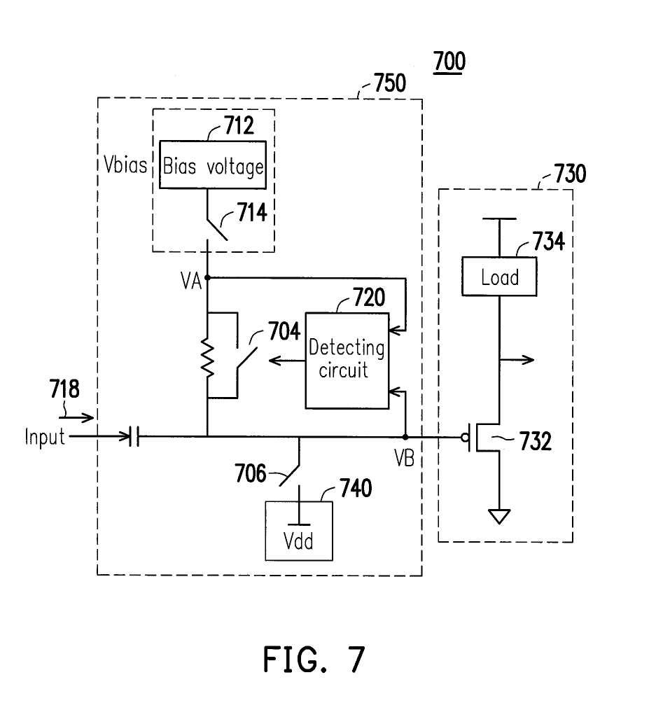

FIG. 7 is a schematic diagram of a fast bias circuit and a bias and load circuit using the fast bias circuit according to another embodiment of the disclosure. The embodiment of FIG. 7 can be deduced according to the related descriptions of the embodiment of FIG. 2. Similar to the embodiment of FIG. 2, the bias and load circuit 700 includes a target circuit 730 and a fast bias circuit 750. A difference between the embodiments of FIG. 7 and FIG. 2 is that the target circuit 730 of FIG. 7 includes a P-channel metal oxide semiconductor (PMOS) transistor 732 and a load 734. A gate of the PMOS transistor 732 serves as the bias terminal VB of the target circuit 730, a source of the PMOS transistor 732 is coupled to the load 734, and a drain of the PMOS transistor 732 is coupled to the reference voltage (for example, the ground voltage).

Referring to FIG. 7, a third switch 706 is in the turn-on state during the power-on period, and a first switch 704, a second switch 714 and a detecting circuit 720 are all in the turn-off state. Therefore, the reference voltage source 740 can transmit the reference voltage (for example, the system voltage Vdd) to the bias terminal VB of the target circuit 730 through the third witch 706.

During the initialisation period of the power-on period, the second switch 714 is in the turn-on state and the third switch 706 is in the turn-off state, so that the voltage of the node VA is the bias voltage Vbias. The detecting circuit 720 compares the voltage of the node VA and the voltage at the gate VB of the PMOS transistor 732 to obtain a comparison result. Since the comparison result is that the bias voltage Vbias of the node VA is smaller than the system voltage Vdd at the bias terminal VB, the detecting circuit 720 controls the first switch 704 to transit to the turn-on state. Since the first switch 704 is turned on, the node VA is shorted to the bias terminal VB, and the bias terminal VB of the target circuit 730 quickly discharges to a bias voltage source 712.

Referring to FIG. 7, during the initialisation period of the power-on period, when the comparison result of the detecting circuit 720 indicates that the voltage of the node VA is equal to the voltage at the bias terminal VB, the detecting circuit 720 controls the first switch 704 to transit to the turn-off state, and the detecting circuit 720 itself is changed to the turn-off state, and the initialisation period is ended. However, after the initialisation period is ended, since the first switch 704 is in the turn-off state, the first switch 704 does not influence transmission of the input signal 718.

In summary, according to the aforementioned embodiments, besides the problem of the AC coupling bias circuit that the DC offset is amplified by the next stage circuit is avoided, during the power-on period, the detecting circuit in the fast bias circuit is used to determine whether or not to change the state of the switch according to the voltage at the bias terminal, so as to achieve the fast bias effect. Moreover, according to the switched short circuit effect, the RC constant is not limited by the resistance value thereof, so that the bias response time after activation is shortened.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A fast bias circuit, comprising:
a bias unit, providing a bias voltage;
a resistor, having a first terminal coupled to the bias unit to receive the bias voltage, and a second terminal coupled to a bias terminal of a target circuit, wherein the bias terminal is coupled to an input signal of the fast bias circuit;
a first switch, having a first terminal coupled to the first terminal of the resistor, a second terminal coupled to the second terminal of the resistor, and a control terminal; and
a detecting circuit, coupled to the control terminal of the first switch, wherein during an initialisation period, the detecting circuit compares the bias voltage with a voltage at the bias terminal of the target circuit to obtain a comparison result, and controls a conduction state of the first switch according to the comparison result.

2. The fast bias circuit as claimed in claim 1, further comprising:
a capacitor, having a first terminal coupled to the bias terminal of the target circuit, and a second terminal receiving the input signal of the fast bias circuit.

3. The fast bias circuit as claimed in claim 1, wherein the bias unit provides the bias voltage during a power-on period of the target circuit, and does not provide the bias voltage during a power off period of the target circuit.

4. The fast bias circuit as claimed in claim 1, wherein the bias unit comprises:
a bias voltage source, providing the bias voltage; and
a second switch, having a first terminal coupled to the bias voltage source for receiving the bias voltage, and a second terminal coupled to the first terminal of the resistor.

5. The fast bias circuit as claimed in claim 4, wherein the second switch is turned off during a power off period of the target circuit, and the second switch is turned on during a power-on period of the target circuit.

6. The fast bias circuit as claimed in claim 1, wherein the detecting circuit compares the bias voltage with the voltage at the bias terminal of the target circuit during the initialisation period; the detecting circuit controls the first switch to be in a turn-on state when the voltage at the bias terminal of the target circuit does not reach the bias voltage during the initialisation period; the initialisation period is ended when the voltage at the bias terminal of the target circuit reaches the bias voltage; and the detecting circuit controls the first switch to maintain in a turn-off state after the initialisation period is ended.

7. The fast bias circuit as claimed in claim 1, wherein the detecting circuit comprises:
a comparator, having a first input terminal and a second input terminal respectively coupled to the bias unit and the bias terminal of the target circuit, and an output terminal coupled to the control terminal of the first switch; and
a logic unit, coupled to an enabling terminal of the comparator, wherein the logic unit enables the comparator during the initialisation period of a power-on period of the target circuit; the initialisation period is ended when an output of the comparator indicates that the voltage at the bias terminal of the target circuit reaches the bias voltage; and the logic unit keeps disabling the comparator after the initialisation period is ended.

8. The fast bias circuit as claimed in claim 1, further comprising:
a third switch, having a first terminal coupled to the bias terminal of the target circuit, and a second terminal coupled to a reference voltage.

9. The fast bias circuit as claimed in claim 8, wherein the third switch is in a turn-off state during a power-on period of the target circuit, and in a turn-on state during a power off period of the target circuit.

10. A bias and load circuit, comprising:
the fast bias circuit as claimed in claim 1; and
the target circuit, driven by the fast bias circuit during a power-on period, and is not driven by the fast bias circuit during a power off period.

11. The bias and load circuit as claimed in claim 10, wherein the target circuit comprises:
a load; and
a switch device, coupled between the load and a reference voltage, and turned on or turned off according to a voltage at the bias terminal.

12. The bias and load circuit as claimed in claim 11, wherein the switch device comprises a switch transistor having a first source/drain coupled to the load, a second source/drain coupled to the reference voltage, and a gate serving as the bias terminal.

13. The bias and load circuit as claimed in claim 10, wherein the bias unit comprises:
a bias voltage source, providing the bias voltage; and
a second switch, having a first terminal coupled to the bias voltage source for receiving the bias voltage, and a second terminal coupled to the first terminal of the resistor.

14. The bias and load circuit as claimed in claim 13, wherein the second switch is turned off during the power off period of the target circuit, and the second switch is turned on during the power-on period of the target circuit.

15. The bias and load circuit as claimed in claim 10, wherein the detecting circuit compares the bias voltage with the voltage at the bias terminal of the target circuit during the initialisation period; the detecting circuit controls the first switch to be in a turn-on state when the voltage at the bias terminal of the target circuit does not reach the bias voltage during the initialisation period; the initialisation period is ended when the voltage at the bias terminal of the target circuit reaches the bias voltage; and the detecting circuit controls the first switch to maintain in a turn-off state after the initialisation period is ended.

16. The bias and load circuit as claimed in claim 10, further comprising:
a third switch, having a first terminal coupled to the bias terminal of the target circuit, and a second terminal coupled to a reference voltage.

17. The bias and load circuit as claimed in claim 16, wherein the third switch is in a turn-off state during the power-on period of the target circuit, and in a turn-on state during the power off period of the target circuit.

18. A fast bias method, comprising:
providing a bias voltage to a first terminal of a resistor during a power-on period of a target circuit, wherein a second terminal of the resistor is coupled to a bias terminal of the target circuit, and the bias terminal is coupled to an input signal;
during an initialisation period of the power-on period, comparing the bias voltage with a voltage at the bias terminal of the target circuit to obtain a comparison result; and
determining whether or not to short the second terminal of the resistor to the first terminal of the resistor according to the comparison result.

19. The fast bias method as claimed in claim 18, further comprising:
not to provide the bias voltage to the first terminal of the resistor during a power off period of the target circuit.

20. The fast bias method as claimed in claim 18, wherein the step of determining whether or not to short the second terminal of the resistor to the first terminal of the resistor comprises:
shorting the first terminal and the second terminal of the resistor when the voltage at the bias terminal of the target circuit does not reach the bias voltage during the initialisation period;
ending the initialisation period when the voltage at the bias terminal of the target circuit reaches the bias voltage; and
not to short the first terminal and the second terminal of the resistor after the initialisation period is ended.

21. The fast bias method as claimed in claim 18, further comprising:
coupling the bias terminal of the target circuit to a reference voltage during a power off period of the target circuit; and
removing the reference voltage from the bias terminal of the target circuit during the power-on period.
